(19) United States
(12) Patent Application Publication
(10) Pub. No.: US 2023/0256559 A1
(43) Pub. Date: Aug. 17, 2023

(54) SUBSTRATE POLISHING SYSTEM AND SUBSTRATE POLISHING METHOD

(71) Applicant: KCTECH CO., LTD., Gyeonggi-do (KR)

(72) Inventor: Ji Hoon SON, Gyeonggi-do (KR)

(73) Assignee: KCTECH CO., LTD., Gyeonggi-do (KR)

(21) Appl. No.: 18/012,042

(22) PCT Filed: Jun. 11, 2021
(86) PCT No.: PCT/KR2021/007327

§ 371 Date: Dec. 21, 2022

(30) Foreign Application Priority Data
Jul. 1, 2020 (KR) 10-2020-0080908

(51) Int. Cl. B24B 37/04; B24B 37/013

(52) U.S. Cl. CPC B24B 37/042; B24B 37/013

(57) ABSTRACT

The substrate polishing system, according to an example embodiment, includes a plurality of polishing apparatuses configured to sequentially polish a substrate, and each of the polishing apparatuses includes a polishing platen polishing a substrate, a data collector collecting a signal generated in a polishing process of the substrate, a data analyzer detecting a thickness of a substrate by analyzing the collected signal, and a polishing endpoint detector determining a polishing endpoint of a substrate based on the detected thickness of a substrate, and the plurality of polishing apparatuses is configured to share data with each other, and based on a polishing order of a substrate, the data obtained from one polishing apparatus of the plurality of polishing apparatuses is configured to be reflected in a detection process of a substrate thickness detection of another polishing apparatus of the plurality of polishing apparatuses in next sequence.

### TECHNICAL FIELD

The following description relates to a substrate polishing system and a substrate polishing method.

### BACKGROUND ART

In manufacturing a semiconductor device, a chemical mechanical polishing (CMP) process including polishing, buffing and cleaning is required. The semiconductor device may be configured in a multilayer structure and a transistor device with a diffusion region is provided at a substrate layer. In the substrate layer, a connecting metallic line may be patterned and electrically connected to the transistor device that constitutes a functional device. A patterned conductive layer may be insulated from other conductive layers through an insulator such as silicon dioxide. As more metal layers and corresponding insulating layers are formed, a need to flatten insulators may increase. Without flattening, the production of additional metal layers becomes substantially more difficult because of the many variations in surface morphology. In addition, the metallic line pattern may be formed of an insulator and a metal CMP process may be performed to remove excess metal.

### DISCLOSURE OF THE INVENTION (DISCLOSURE OF THE INVENTION)

### Technical Goals

The example embodiment provides a substrate polishing system and a substrate polishing method for more efficiently detecting a thickness of a substrate in a process of performing continuous substrate polishing.

The example embodiment provides a substrate polishing system and a substrate polishing method that may reduce time required to detect a thickness of a substrate by utilizing data from a previous polishing process.

The technical tasks obtainable from the present disclosure are non-limited by the above-mentioned technical tasks. And, other unmentioned technical tasks may be clearly understood from the following description by those having ordinary skill in the technical field to which the present disclosure pertains.

### Technical Solutions

A substrate polishing system, according to an example embodiment, may include a plurality of polishing apparatuses configured to sequentially polish a substrate, and each of the polishing apparatuses may include a polishing platen polishing a substrate, a data collector collecting a signal generated in a polishing process of the substrate, a data analyzer detecting a thickness of a substrate by analyzing the collected signal, and a polishing endpoint detector determining a polishing endpoint of a substrate based on the detected thickness of a substrate, and the plurality of polishing apparatuses may be configured to share data with each other, and based on a polishing order of a substrate, the data obtained from one polishing apparatus of the plurality of polishing apparatuses may be configured to be reflected in a detection process of a substrate thickness detection of another polishing apparatus of the plurality of polishing apparatuses in next sequence.

On one side, data shared by the plurality of polishing apparatuses may include at least one of a signal generated during a polishing process of a substrate in each polishing apparatus, a signal analysis result of each data analyzer, a result of detecting a thickness of a substrate, and information on a polishing endpoint of a substrate in each polishing apparatus.

On one side, one polishing apparatus in which polishing of the substrate is performed may detect a real-time thickness of a substrate by interpolating real-time data generated in a polishing process of a substrate to data acquired from a polishing apparatus in which the substrate was polished immediately before.

The substrate polishing system according to an example embodiment may include a first polishing apparatus including a first polishing platen for performing a first polishing process of a substrate and a first analysis module for detecting a real-time thickness of the substrate by analyzing a signal generated in the first polishing process, and a second polishing apparatus including a second polishing platen for performing a second polishing process of a substrate in a state in which the first polishing process is completed and a second analysis module for detecting a real-time thickness of the substrate by analyzing a signal generated in the second polishing process, and the second analysis module may collect first data of the first analysis module and detect a real-time thickness of the substrate in the second polishing process based on the collected first data.

On one side, the second analysis module may detect a real-time thickness of a substrate in a second polishing process through first data during a first-time from a first-time point to a polishing endpoint of the first polishing process.

On one side, the second analysis module may generate integrated data during a third-time by combining second data including from an initial time point to a second-time point of a second polishing process with first data during the first-time and detect a thickness of a substrate at a second-time point through the generated integrated data.

A substrate polishing method, according to an example embodiment, may include a first polishing of performing a first polishing process of a substrate through a first polishing platen, a first detecting of polishing detecting a real-time thickness of a substrate in a first polishing process based on first data generated in the first polishing process, a second polishing of performing a second polishing process of the substrate through a second polishing platen after the first polishing process is completed, and a second detecting of polishing detecting a real-time thickness of a substrate in a second polishing process based on the first data acquired in the first detecting of polishing and second data generated in the second polishing process.

On one side, the first detecting of polishing may obtain an analysis result on a real-time thickness of a substrate based on data during a first detection time including an initial time point in a first sequence of the first polishing process.

On one side, the second detecting of polishing may acquire an analysis result on a real-time thickness of a substrate by integrating data during a first acquisition time including a polishing endpoint in the first sequence and data during a second detection time including an initial time point in a second sequence of the second polishing process.

On one side, the second detection time may be shorter than the first detection time.

### Effects

The substrate polishing system and substrate polishing method according to an example embodiment may more efficiently detect a thickness of a substrate in a process of performing continuous polishing of a substrate.

The substrate polishing system and substrate polishing method according to an example embodiment may reduce time required for detecting a thickness of a substrate by utilizing data from a previous polishing process.

The effects of the substrate polishing system and substrate polishing method according to an example embodiment are not limited to the above-mentioned effects, and other unmentioned effects may be clearly understood from the following description by one of ordinary skill in the art.

### BRIEF DESCRIPTION OF DRAWINGS

The accompanying drawings illustrate preferred example embodiments of the present disclosure, and are provided together with the detailed description for better understanding of the technical idea of the present disclosure. Therefore, the present disclosure should not be construed as being limited to the example embodiments set forth in the drawings.

FIG. 1 is a block diagram illustrating a substrate polishing system according to an example embodiment;

FIG. 2 is a graph illustrating a signal generated in a substrate polishing process according to an example embodiment.

FIG. 3 is a graph illustrating a method for detecting a thickness of a substrate polishing system according to an example embodiment; and

FIG. 4 is a flowchart illustrating a substrate polishing method according to an example embodiment.

### BEST MODE FOR CARRYING OUT THE INVENTION

Hereinafter, embodiments of the present disclosure will be described with reference to the accompanying drawings. Regarding the reference numerals assigned to the components in the drawings, it should be noted that the same components will be designated by the same reference numerals, wherever possible, even though they are shown in different drawings. Also, in the description of the embodiments, detailed description of well-known related structures or functions will be omitted when it is deemed that such description will cause ambiguous interpretation of the present disclosure.

Also, in the description of the components, terms such as first, second, A, B, (a), (b) or the like may be used herein when describing components of the present disclosure. These terms are used only for the purpose of discriminating one constituent element from another constituent element, and the nature, the sequences, or the orders of the constituent elements are not limited by the terms. When one constituent element is described as being “connected”, “coupled”, or “attached” to another constituent element, it should be understood that one constituent element can be connected or attached directly to another constituent element, and an intervening constituent element can also be “connected”, “coupled”, or “attached” to the constituent elements.

The same name may be used to describe an element included in the examples described above and an element having a common function. Unless otherwise mentioned, the descriptions of the embodiments may be applicable to the following embodiments and thus, duplicated descriptions will be omitted for conciseness.

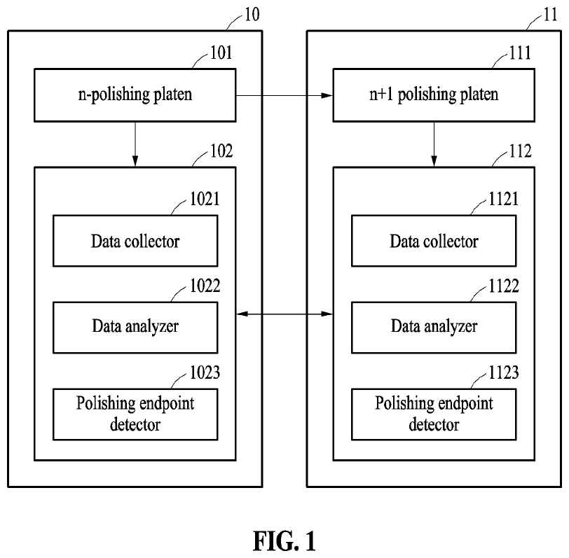

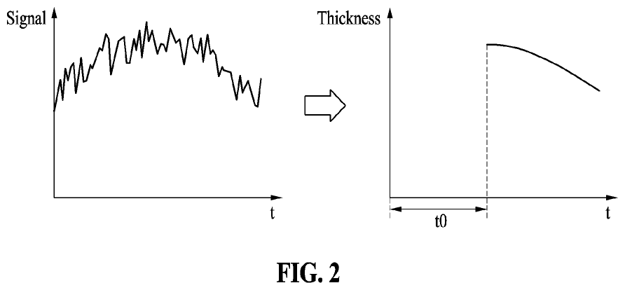

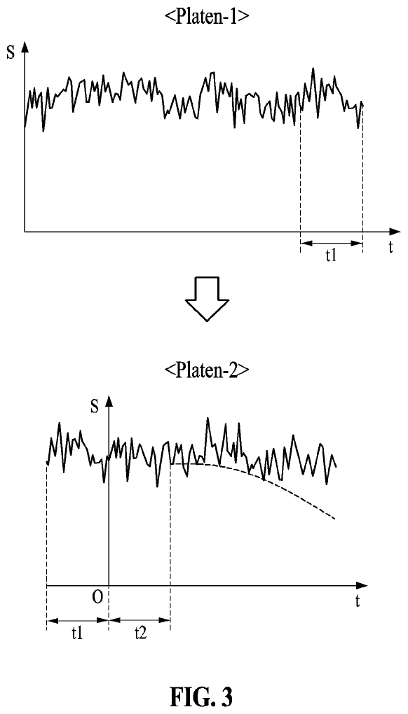

FIG. 1 is a block diagram illustrating a substrate polishing system according to an example embodiment. FIG. 2 is a graph illustrating a signal generated in a substrate polishing process according to an example embodiment. FIG. 3 is a graph illustrating a method for detecting a thickness of a substrate polishing system according to an example embodiment.

Referring to FIGS. 1 to 3, a substrate polishing system according to an example embodiment may be used for polishing a substrate. The substrate polishing system may sequentially perform a plurality of polishing processes on one substrate. According to a set profile, each polishing process may obtain a profile of a target substrate surface by sequentially polishing a surface of a substrate. The substrate polishing system may efficiently and accurately polish a surface of a substrate by sharing data generated in a plurality of polishing processes with each other and utilizing the shared data.

The substrate polishing system may include a plurality of polishing apparatuses 10 and 11. The plurality of polishing apparatuses 10 and 11 may perform individual polishing processes for a substrate. By sequentially moving a plurality of polishing apparatuses 10 and 11, a surface of one substrate may be polished according to the set profile of each polishing apparatuses 10 and 11. When there is a plurality of polishing apparatuses 10 and 11, a substrate passed through an n-th polishing apparatus may be moved to an n+1-th polishing apparatus to perform polishing. Hereinafter, for ease of description, it is assumed that the substrate polishing system includes two polishing apparatuses. A polishing apparatus in which a polishing process is performed for the first-time is referred to as a first polishing apparatus 10, and a polishing apparatus that performs polishing of a substrate after the first polishing apparatus is referred to as a second polishing apparatus 11.

The substrate may be a silicon wafer for manufacturing a semiconductor. For example, the substrate may include glass for a flat panel display device (FPD) such as a liquid crystal display (LCD) or a plasma display panel (PDP). A plurality of layers formed of a metal or a non-metal may be stacked on a surface of a substrate. By sequentially polishing the layers formed on a surface of a substrate, each polishing apparatus may allow a layer thickness of an outer surface of the substrate to reach a target value.

Each polishing apparatus 10 may include a polishing platen 101 and an analysis module 102.

The polishing platen 101 may perform polishing of a substrate. The polishing platen 101 may include a polishing pad for physically and chemically polishing a substrate surface by being in contact with a substrate surface. The substrate is transported to the polishing platen by a substrate carrier (not shown) and the surface may be polished while in contact with the polishing platen.

While polishing a substrate on the polishing platen 101, various signals may be generated according to a surface profile of the substrate. For example, when the polishing platen 101 polishes a metal layer of a substrate, the polishing platen 101 may include a magnetic sensor for detecting a thickness change of the metal layer. However, it is merely an example, and the polishing platen 101 may include various types of sensors for detecting signals generated according to the surface profile of the substrate, for example, an eddy-current sensor, an optical sensor, a motor sensor, an acoustic sensor, and the like.

The analysis module 102 may detect a real-time thickness of a substrate by analyzing a signal generated in a process of polishing a substrate in the polishing platen. The analysis module 102 may include a data collector 1021, a data analyzer 1022, and a polishing endpoint detector 1023.

The data collector 1021 may collect signals generated in a polishing process of a substrate. The signals collected by the data collector 1021 may include various types of signals such as magnetic signals, optical signals, current changes, loads applied to the motor, noise, and the like.

The data analyzer 1022 may detect a thickness of a substrate by analyzing the signal collected by the data collector 1021. The data analyzer 1022 may secure real-time prediction data for a thickness of a substrate by correcting a signal change over time according to a set algorithm.

The polishing endpoint detector 1023 may determine a polishing endpoint of a substrate through prediction data for the detected substrate thickness. When the polishing endpoint of a substrate is determined, the polishing of a substrate on the polishing platen 101 may be finished.

A plurality of polishing apparatuses may share data with each other. Data obtained by an n-th polishing apparatus 10 based on a polishing order of a substrate may be reflected in a detection process of a substrate thickness of an n+1-th polishing apparatus 11. The data shared by a plurality of polishing apparatuses may include at least one of collection data of signals generated in a substrate polishing process in each polishing apparatus, signal analysis data of each data analyzer, result data for a substrate thickness detection, and information data on a polishing endpoint of a substrate.

The n+1th polishing apparatus 11 may secure a result on a thickness of a substrate by utilizing data obtained by the n-th polishing apparatus 10 in the polishing process of a substrate. For example, referring to FIG. 2, change data of a signal for a predetermined period is required to detect a thickness of a substrate. The signal generated in a polishing process of a substrate may be transformed to data on a thickness of a substrate by being corrected by a set algorithm. That is, in order to secure a prediction result for a thickness of a substrate, data on a signal change for a predetermined time t0 may be required. Thus, a precise polishing control of a substrate may be performed only when the detection result of the substrate thickness is secured after a predetermined time t0 has elapsed.

Since the substrate polishing system detects a thickness of a substrate by using data of the n-th polishing process in the n+1-th polishing process, it is possible to reduce the time for securing result data on a substrate thickness.

Referring to FIG. 3, a substrate polishing process using two polishing apparatuses will be described.

The first polishing apparatus 10 may perform a first polishing process on a substrate. The first polishing apparatus 10 may polish a substrate through the first polishing platen 101 and analyze the signal generated during the first polishing process through the first analysis module 102 to secure result data on a real-time thickness of a substrate

When the polishing of a substrate in the first polishing apparatus 10 is completed, the substrate moves to the second polishing apparatus 11 to perform a second polishing process. The second polishing apparatus 11 may include a second polishing platen 111 for performing a second polishing process of a substrate and a second analysis module 112 for detecting a real-time thickness of a substrate by analyzing signals generated in a second polishing process. In this case, the second analysis module 112 may collect first data for the first polishing process from the first analysis module 102 and may detect a real-time thickness of a substrate in the second polishing process based on the collected first data.

The second analysis module 112 may utilize data during a first-time t1 including from a first-time point to a polishing endpoint in a first sequence of a first polishing process. The second analysis module 112 may generate integrated data during a third-time t1+t2 by combining second data during a second-time t2 including from an initial time point to a second-time point of a second polishing process with first data during a first-time t1.

In this case, the second analysis module 112 may detect a thickness of a substrate at the second-time point through the generated integrated data. In the case of detecting a thickness of a substrate through the integrated data, since data during the first-time t1 in the first polishing process performed immediately before the second polishing process is used, it is possible to reduce the time to detect a thickness of a substrate in the second polishing process.

That is, since the substrate polishing system corrects an unstable sensor signal that appears at the beginning of each polishing process through signals collected from a plurality of polishing platens, the time required in the process of detecting a thickness of a substrate may be reduced and a more accurate substrate thickness profile may be performed.

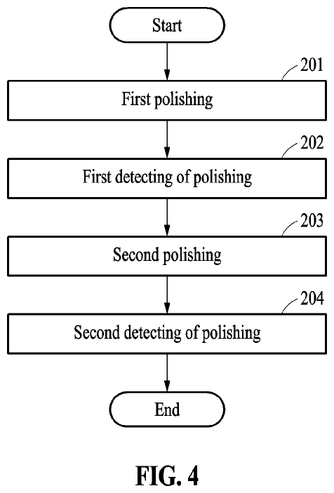

FIG. 4 is a flowchart illustrating a substrate polishing method according to an example embodiment.

When describing of a substrate polishing method, a duplicate description will be omitted for conciseness.

Referring to FIG. 4, the substrate polishing method may include a first polishing 201, a first detecting of polishing 202, a second polishing 203, and a second detecting of polishing 204.

The first polishing 201 may perform a first polishing process of a substrate through a first polishing platen.

The first detecting of polishing 202 may detect a real-time thickness of a substrate during the first polishing process based on the first data generated in the first polishing process. In this case, the first data may include data on a thickness of a substrate according to various signal data generated during the first polishing process, analysis data that analyzed the signal data according to the set algorithm, and data on a thickness of a substrate according to the analysis result.

The first detecting of polishing 202 may obtain an analysis result on a real-time thickness of a substrate based on data during a first detection time including an initial time point in the first sequence of the first polishing process. That is, real-time data for a predetermined time may be required to obtain an analysis result on a thickness of a substrate.

The second polishing 203 may perform a second polishing process of a substrate through a second polishing platen after the first polishing process is completed.

The second detecting of polishing 204 may detect a real-time thickness of a substrate in the second polishing process based on the first data obtained in the first polishing detection 202 and the second data generated in the second polishing process.

The second detecting of polishing 204 may include an analysis result on a real-time thickness of a substrate by integrating data during a first acquisition time including a polishing endpoint of the first polishing process in the first sequence and data during a second acquisition time including an initial time point in the second sequence of the second polishing process. That is, the second detecting of polishing may reduce the time required for predicting a thickness of a substrate in the second polishing process by using some of the real-time data for analyzing a thickness of a substrate as the data of the first polishing.

Accordingly, the second detection time required for detecting a thickness of a substrate in the second detecting of polishing 204 may be shorter than the first detection time required for detecting a thickness of a substrate in the first detecting of polishing 202.

A number of example embodiments have been described above. Nevertheless, it should be understood that various modifications may be made to these example embodiments. For example, suitable results may be achieved if the described techniques are performed in a different order and/or if components in a described system, architecture, device, or circuit are combined in a different manner and/or replaced or supplemented by other components or their equivalents.

1. A system of polishing a substrate, the system comprising:
a plurality of polishing apparatuses configured to sequentially polish a substrate,
wherein each of the polishing apparatuses comprising:
a polishing platen polishing a substrate;
a data collector collecting a signal generated in a polishing process of the substrate;
a data analyzer detecting a thickness of a substrate by analyzing the collected signal; and
a polishing endpoint detector determining a polishing endpoint of a substrate based on the detected thickness of a substrate,
wherein the plurality of polishing apparatuses is configured to share data with each other, and
wherein based on a polishing order of a substrate, the data obtained from one polishing apparatus of the plurality of polishing apparatuses is configured to be reflected in a detection process of a substrate thickness detection of another polishing apparatus of the plurality of polishing apparatuses in next sequence.

2. The system of claim 1, wherein data shared by the plurality of polishing apparatuses comprises at least one of a signal generated during a polishing process of a substrate in each polishing apparatus, a signal analysis result of each data analyzer, a result of detecting a thickness of a substrate, and information on a polishing endpoint of a substrate in each polishing apparatus.

3. The system of claim 1, wherein one polishing apparatus in which polishing of the substrate is performed is configured to detect a real-time thickness of a substrate by utilizing real-time data generated in a polishing process of a substrate to data acquired from a polishing apparatus in which the substrate was polished immediately before.

4. A system of polishing a substrate, the system comprising:
a first polishing apparatus comprising a first polishing platen performing a first polishing process of a substrate and a first analysis module detecting a real-time thickness of the substrate by analyzing a signal generated in the first polishing process; and
a second polishing apparatus comprising a second polishing platen performing a second polishing process of a substrate in a state in which the first polishing process is completed and a second analysis module detecting a real-time thickness of the substrate by analyzing a signal generated in the second polishing process,
wherein the second analysis module is configured to collect first data of the first analysis module and detect a real-time thickness of the substrate in the second polishing process based on the collected first data.

5. The system of claim 4, wherein the second analysis module is configured to detect a real-time thickness of a substrate in a second polishing process through first data during a first-time from a first-time point to a polishing endpoint of the first polishing process.

6. The system of claim 5, wherein the second analysis module is configured to:
generate integrated data during a third-time by combining second data during a second-time comprising from an initial time point to a second-time point of a second polishing process with first data during the first-time; and
detect a thickness of a substrate at a second-time point through the generated integrated data.

7. A method of polishing a substrate, the method comprising:
a first polishing of performing a first polishing process of a substrate through a first polishing platen;
a first detecting of polishing detecting a real-time thickness of a substrate in a first polishing process based on first data generated in the first polishing process;
a second polishing of performing a second polishing process of the substrate through a second polishing platen after the first polishing process is completed; and
a second detecting of polishing detecting a real-time thickness of a substrate in a second polishing process based on the first data acquired in the first detecting of polishing and second data generated in the second polishing process.

8. The method of claim 7, wherein the first detecting of polishing is configured to obtain an analysis result on a real-time thickness of a substrate based on data during a first detection time comprising an initial time point in a first sequence of the first polishing process.

9. The method of claim 8, wherein the second detecting of polishing is configured to acquire an analysis result on a real-time thickness of a substrate by integrating data during a first acquisition time comprising a polishing endpoint in the first sequence and data during a second detection time comprising an initial time point in a second sequence of the second polishing process.

10. The method of claim 9, wherein the second detection time is shorter than the first detection time.
